(19) United States
(12) Patent Application Publication
(10) Pub. No.: US 2026/0040656 A1
(43) Pub. Date: Feb. 5, 2026

(54) GATE OXIDE LAYER INCLUDING NITROGEN FOR SEMICONDUCTOR DEVICE

(71) Applicant: TEXAS INSTRUMENTS INCORPORATED, Dallas, TX (US)

(72) Inventors: Mahalingam Nandakumar, Richardson, TX (US); Isaac Curtis, Sandy, UT (US); Divya Mishra, Lehi, UT (US); Patrick James Wester, Salt Lake City, UT (US)

(21) Appl. No.: 18/789,855

(22) Filed: Jul. 31, 2024

(51) Int. Cl. H01L 29/51; H01L 21/28; H01L 29/423

(52) U.S. Cl. CPC H10D 64/693; H01L 21/28202; H10D 64/514

(57) ABSTRACT

The present disclosure generally relates to semiconductor processing for forming a gate oxide layer and a corresponding semiconductor device. In an example, a semiconductor device includes a semiconductor substrate, a gate oxide layer, a gate electrode, a first source/drain region, and a second source/drain region. The gate oxide layer is on the semiconductor substrate. The gate oxide layer has a thickness less than or equal to 25 Angstroms. The gate oxide layer includes nitrogen and includes a peak concentration of nitrogen that is equal to or greater than 20 atomic percent. The gate electrode is over the gate oxide layer. The first source/drain region is in the semiconductor substrate. The second source/drain region is in the semiconductor substrate. The first source/drain region and the second source/drain region are on opposing lateral sides of the gate electrode.

### BACKGROUND

In integrated circuits (ICs), various semiconductor devices have components formed in or on a semiconductor substrate. For decades, sizes of various semiconductor devices have decreased. Moore's Law has historically indicated a decreasing size of semiconductor devices, and conversely, an increase in density of semiconductor devices, in ICs. The reduction of size of some semiconductor devices has caused various challenges and problems for manufacturing those semiconductor devices.

### SUMMARY

An example is a semiconductor device. The semiconductor device includes a semiconductor substrate, a gate oxide layer, a gate electrode, a first source/drain region, and a second source/drain region. The gate oxide layer is on the semiconductor substrate. The gate oxide layer has a thickness less than or equal to 25 Angstroms. The gate oxide layer includes nitrogen and includes a peak concentration of nitrogen that is equal to or greater than 20 atomic percent. The gate electrode is over the gate oxide layer. The first source/drain region is in the semiconductor substrate. The second source/drain region is in the semiconductor substrate. The first source/drain region and the second source/drain region are on opposing lateral sides of the gate electrode.

Another example is a method. A gate oxide layer is formed on a semiconductor substrate. Forming the gate oxide layer includes oxidizing a surface of the semiconductor substrate. A nitridation process is performed on the gate oxide layer. A post-nitridation anneal is performed on the gate oxide layer after performing the nitridation process. The post-nitridation anneal includes at least one of: performing a spike anneal at a temperature equal to or greater than 1,100° C.; and performing a laser anneal at a temperature equal to or greater than 1,250° C.

A further example is a semiconductor device. The semiconductor device includes a semiconductor substrate and a nitrided oxide layer on the semiconductor substrate. The nitrided oxide layer has a thickness less than or equal to 25 Angstroms. The nitrided oxide layer includes a peak concentration of nitrogen that is equal to or greater than 20 atomic percent. A concentration of nitrogen in the nitrided oxide layer at an interface between the nitrided oxide layer and the semiconductor substrate is less than 2 atomic percent.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a flow chart of a method for manufacturing a semiconductor device according to some examples.

FIGS. 2, 3, 4, 5, 6, 7, and 8 are respective cross-sectional views of a semiconductor device in intermediate stages of manufacturing according to some examples.

FIGS. 9A, 9B, and 9C are charts illustrating process parameters for a spike anneal according to some examples.

FIGS. 10A and 10B are charts of an oxygen concentration profile and a nitrogen concentration profile, respectively, across a gate oxide layer and into a semiconductor substrate according to an example.

FIGS. 11A and 11B are charts of an oxygen concentration profile and a nitrogen concentration profile, respectively, across a gate oxide layer and into a semiconductor substrate according to another example.

FIG. 12 is a chart depicting drain-to-source on current (Ips) versus off current (IOFF) for n-channel field effect transistors (nFETs) manufactured according to an example and nFETs manufactured according to a previous method.

FIGS. 13A and 13B are charts depicting gate oxide layer thickness versus gate leakage for nFETs and p-channel field effect transistors (pFETs), respectively, manufactured according to an example and nFETs and pFETs, respectively, manufactured according to a previous method.

FIGS. 14A and 14B are charts depicting gate oxide layer thickness versus gate leakage for nFETs and pFETs, respectively, manufactured according to multiple examples and nFETs and pFETs, respectively, manufactured according to a previous method.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to semiconductor processing for forming a gate oxide layer and a corresponding semiconductor device. The gate oxide layer may be implemented in a field effect transistor (FET), for example. The gate oxide layer includes nitrogen (e.g., is nitrided). The gate oxide layer has a thickness equal to or less than 25 Angstroms while having a peak concentration of nitrogen equal to or greater than 20 atomic percent. A concentration of the nitrogen in the gate oxide layer at an interface with a semiconductor substrate on which the gate oxide layer is formed may be equal to or less than 2 atomic percent. The gate oxide layer may be formed by oxidizing a surface of the semiconductor substrate, performing a nitridation on the gate oxide layer, and performing a post-nitridation anneal on the gate oxide layer. The post nitridation anneal may include performing a spike anneal at a temperature equal to or greater than 1,100° C. and/or performing a laser anneal at a temperature equal to or greater than 1,250° C. Forming such a gate oxide layer may prevent significant penetration of nitrogen into the semiconductor substrate (e.g., into a channel region of a FET) while achieving a target nitrogen concentration in the gate oxide layer and while scaling the gate oxide layer to a smaller thickness.

Other known methods for forming a gate oxide layer that includes nitrogen, when scaled to a thickness equal to or less than 25 Angstroms, could not achieve a target peak nitrogen concentration, such as equal to or greater than 20 atomic percent, and/or would incur significant nitrogen penetration into the semiconductor substrate (e.g., a channel region of a FET). Having too low of a concentration of nitrogen in a gate oxide layer may not sufficiently prevent boron (B) from migrating or penetrating into the semiconductor substrate from a doped polysilicon gate electrode, which may result in significant gate leakage problems. Having too much penetration of nitrogen in the semiconductor substrate (e.g., a channel region) may cause degradation of device performance, such as increased drain-to-source resistance (Rps) and reduced drain-to-source on current (Ips). Various examples described herein obviate such challenges and problems and may achieve improved gate leakage and improved drain-to-source on current (Ips) versus off current (IOFF). Other benefits and advantages may be achieved.

Various examples are described subsequently. Although the specific examples may illustrate various aspects of the above generally described features, examples may incorporate any combination of the above generally described features (which are described in more detail in examples below).

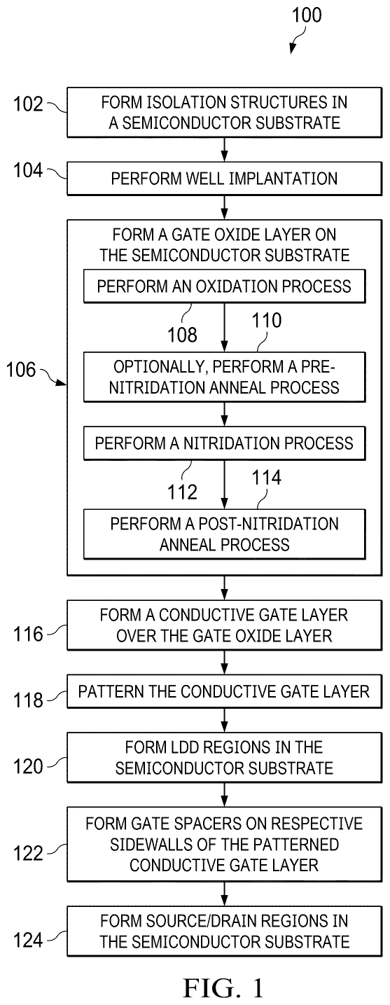

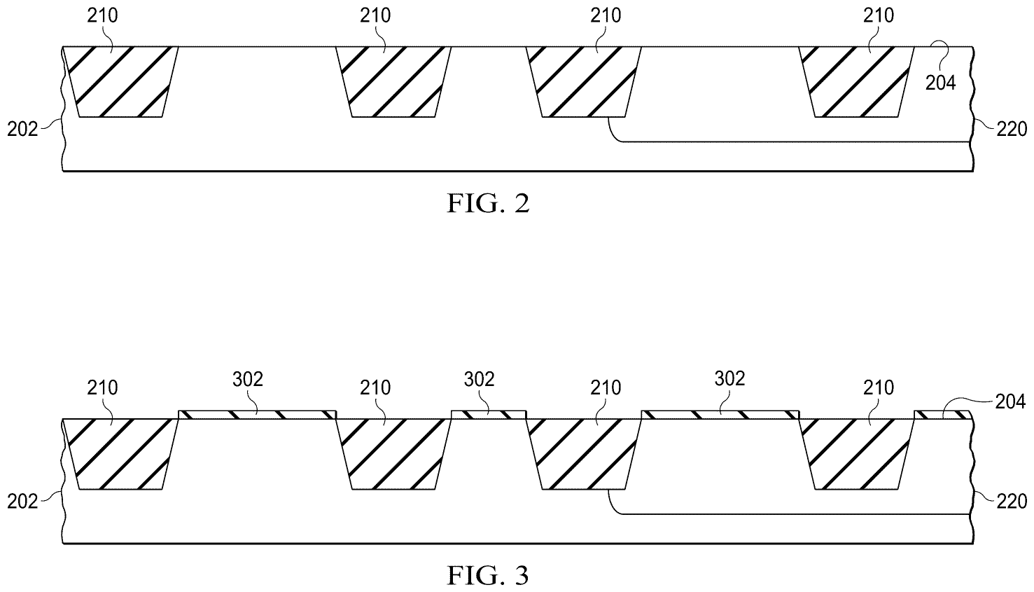

FIG. 1 is a flow chart of a method 100 for manufacturing a semiconductor device according to some examples. FIGS. 2 through 8 are respective cross-sectional views of a semiconductor device in intermediate stages of manufacturing according to some examples. The method 100 of FIG. 1 is described herein in the context of FIGS. 2 through 8.

Referring to block 102 of FIG. 1 and to FIG. 2, isolation structures 210 are formed in a semiconductor substrate 202. The semiconductor substrate 202 may be or include a bulk semiconductor substrate, a semiconductor-on-insulator (SOI) substrate, or any other appropriate substrate. The semiconductor substrate 202 may also include a support (or handle) substrate and an epitaxial layer epitaxially grown on the support substrate. In some examples, the semiconductor substrate 202 is or includes a silicon substrate (which may be singulated from a bulk silicon wafer at the conclusion of semiconductor processing). In further examples, the semiconductor substrate 202 includes a silicon substrate with an epitaxial silicon layer grown thereon. The semiconductor substrate 202 is or includes a semiconductor material in and/or on which devices, such as a p-channel FET (pFET) and an n-channel FET (nFET) (as described subsequently), are formed. In some examples, the semiconductor material is or includes silicon (Si), silicon germanium (SiGe), gallium arsenide (GaAs), gallium nitride (GaN), the like, or a combination thereof. The semiconductor substrate 202 has an upper surface 204 in and/or on which devices (e.g., the pFET and nFET) are formed. In the illustrated example, the semiconductor material of the semiconductor substrate 202 is p-doped with a p-type dopant. In some examples, the semiconductor substrate 202 is p-doped with a p-type dopant (e.g., boron (B)) with a concentration in a range from 1×10¹⁴ cm⁻³ to 1×10¹⁵ cm⁻³. Another dopant type and/or other doping concentrations may be implemented.

In the illustrated example, the isolation structures 210 are shallow trench isolation structures (STIs) extending from the upper surface 204 of the semiconductor substrate 202 into the semiconductor substrate 202. In the illustrated example, the isolation structures 210 may have respective upper surfaces co-planar with the upper surface 204 of the semiconductor substrate 202. In other examples, the isolation structures 210 may have respective upper surfaces above and/or may be below the upper surface 204 of the semiconductor substrate 202. The isolation structures 210 may include, for example, a liner layer, such as including silicon oxide or silicon nitride, conformally along surfaces of a respective trench in the semiconductor substrate 202 and a fill isolation material, such as silicon oxide, over and on the liner layer.

The isolation structures 210 may be formed by depositing a hardmask layer over the semiconductor substrate 202. The hardmask layer may be any appropriate material, such as silicon nitride, silicon oxynitride, or the like, and may be deposited using any appropriate deposition process, such as chemical vapor deposition (CVD). The hardmask layer is patterned, such as by using photolithography and an etching process (e.g., reactive ion etch (RIE)). Recesses or trenches are etched, such as by RIE, in the semiconductor substrate 202 using the patterned hardmask layer as a mask. The liner layer may then be conformally formed or deposited in the recesses or trenches and may be deposited over the patterned hardmask layer, such as by an oxidation process, plasma enhanced CVD (PECVD), or the like. The fill isolation material may be deposited over the liner layer, such as by high aspect ratio CVD (HAR-CVD), flowable CVD (FCVD), or the like. Excess fill isolation material and liner layer may be removed from over the hardmask layer by a planarization process, such as a chemical mechanical polish (CMP). The hardmask layer may then be removed by the planarization process and/or an etch selective to the hardmask layer, which may be a wet etch process. In other examples, the isolation structures 210 may be field oxide structures, such as local oxidation of silicon (LOCOS) structures, at the upper surface 204 of the semiconductor substrate 202, which may be formed using a LOCOS process.

The isolation structures 210 laterally define respective active areas of the upper surface 204 of the semiconductor substrate 202 on which the pFET and nFET are to be formed. Respective isolation structures 210 laterally encircle the active area of the upper surface 204 of the semiconductor substrate 202 on which the pFET is to be formed, as indicated subsequently. Similarly, respective isolation structures 210 laterally encircle the active area of the upper surface 204 of the semiconductor substrate 202 on which the nFET is to be formed, as indicated subsequently.

Referring to block 104 of FIG. 1 and to FIG. 2, well implantation is performed. One or more wells may be formed by implantation. For example, one or more n-type doped wells may be formed by implantation, and one or more p-type doped wells may be formed by implantation. One or more n-type doped wells may be formed by masking (e.g., by a photoresist using photolithography) areas of the semiconductor substrate 202 where an n-type doped well is not to be formed and implanting n-type dopants into the semiconductor substrate 202. Similarly, one or more p-type doped wells may be formed by masking (e.g., by a photoresist using photolithography) areas of the semiconductor substrate 202 where a p-type doped well is not to be formed and implanting p-type dopants into the semiconductor substrate 202. Any doped well may extend from the upper surface 204 of the semiconductor substrate 202 into a depth in the semiconductor substrate 202, which may be to a level below, at, or above a bottom surface of the isolation structures 210. As illustrated in FIG. 2, an n-type doped well 220 is formed by an implantation at block 104. The n-type doped well 220 is formed in a region of the semiconductor substrate 202 where the pFET is to be formed. In some examples, a p-type doped well may be formed in a region of the semiconductor substrate 202 where the nFET is to be formed. A concentration of the n-type dopant of the n-type doped well 220 is greater than a concentration of the p-type dopant of the p-type doped semiconductor substrate 202. In some examples, the n-type doped well 220 is doped with an n-type dopant (e.g., phosphorus (P) or arsenic (As)) with a concentration in a range from 1×10¹⁵ cm⁻³ to 1×10¹⁷ cm⁻³. If a p-type well is formed, a concentration of the p-type dopant of the p-type doped well may be greater than a concentration of the p-type dopant of the p-type doped semiconductor substrate 202. In some examples, the p-type doped well may be doped with a p-type dopant (e.g., boron (B)) with a concentration in a range from 1×10¹⁵ cm⁻³ to 1×10¹⁷ cm⁻³. Other doping concentrations may be implemented for the doped well(s).

Referring to block 106 of FIG. 1 and to FIG. 3, a gate oxide layer 302 is formed on the semiconductor substrate 202. The gate oxide layer 302 may be, for example, a silicon oxide that includes nitrogen. The gate oxide layer 302 may be a silicon oxide that is nitrided by a nitridation process. Forming the gate oxide layer 302 of block 106 includes performing an oxidation process at block 108; optionally, performing a pre-nitridation anneal process at block 110; performing a nitridation process at block 112; and performing a post-nitridation anneal process at block 114.

The oxidation process at block 108 forms an oxide layer at the upper surface 204 of the semiconductor substrate 202. The oxidation process may be or include an in situ steam generation (ISSG) oxidation. The ISSG oxidation may include flowing a gas mixture including nitrous oxide (N₂O) gas and hydrogen (H₂) gas in a processing chamber in which the semiconductor substrate 202 is located. A flow rate of the nitrous oxide (N₂O) gas into the processing chamber may be in a range from 5,000 standard cubic centimeters per minute (sccm) to 50,000 sccm, and a flow rate of the hydrogen (H₂) gas into the processing chamber may be in a range from 50 sccm to 5,000 sccm. The ISSG oxidation may be performed at a temperature in a range from 950° C. to 1,050° C. in the processing chamber. Generally, the gases flowed into the processing chamber react and/or decompose such that oxygen reacts with the semiconductor material at the upper surface 204 of the semiconductor substrate 202. In examples in which the semiconductor material is silicon, the ISSG oxidation forms silicon oxide. In some examples, no significant quantity of nitrogen is formed in the oxide formed at the upper surface 204 of the semiconductor substrate by the ISSG oxidation. Nitrogen from the nitrous oxide (N₂O) gas generally does not react with the semiconductor material at the upper surface 204 and is flowed out or purged from the processing chamber. In examples in which block 110 is optionally omitted, the oxide layer formed at block 108 may have a thickness in a range from 16 Angstroms to 21 Angstroms. In other examples in which block 110 is performed, the oxide layer formed at block 108 may have a thinner thickness, such as in a range from 14 Angstroms to 19 Angstroms.

The pre-nitridation anneal of block 110, if performed, may further oxidize the upper surface 204 of the semiconductor substrate 202 and cause the oxide layer formed at block 108 to become thicker. The pre-nitridation anneal may be at a temperature equal to or greater than 1,050° C. for a duration of less than 5 seconds, such as equal to or less than 3 seconds. The pre-nitridation anneal may include flowing a gas mixture including nitrogen (N₂) gas and oxygen (O₂) gas in a processing chamber in which the semiconductor substrate 202 is located. A flow rate of the nitrogen (N₂) gas into the processing chamber may be in a range from 5,000 sccm to 20,000 sccm, and a flow rate of the oxygen (O₂) gas into the processing chamber may be in a range from 50 sccm to 4,000 sccm. In some examples, the flow rate of the oxygen (O₂) gas may be in a range from 0.1% to 10% of the combined flow of the oxygen (O₂) gas and the nitrogen (N₂) gas. In some examples, the oxidation process of block 108 and the pre-nitridation anneal of block 110 are performed in a same processing chamber. The oxidation that may occur in the pre-nitridation anneal may improve an oxide-silicon interface (where silicon is the semiconductor material being oxidized) by the pre-nitridation anneal implementing a temperature equal to or greater than 1,050° C. The oxide layer formed by the oxidation process of block 108 may be grown to be thicker by the pre-nitridation anneal of block 110, such as in a range from 1 Angstroms to 5 Angstroms thicker. Hence, after the pre-nitridation anneal of block 110, the oxide layer may be in a range from 15 Angstroms to 21 Angstroms.

The nitridation process at block 112 causes the oxide layer to be nitrided or to include nitrogen. In some examples, the nitridation process is a decoupled plasma nitridation (DPN). As an example, a DPN may be performed in an inductively coupled plasma (ICP) processing chamber with flowing nitrogen (N₂) gas in a low energy plasma (e.g., equal to or less than 2 kilowatts (KW)). A duty cycle of the power (e.g., percentage of time power is on relative to total time) may be in a range from 5% to 40%. A flow rate of the nitrogen (N₂) gas in the DPN may be in a range from 100 sccm to 600 sccm. The DPN may be performed at a temperature in a range from 20° C. to 40° C. in the processing chamber. The DPN may be performed at a pressure in a range from 5 milliTorr (mTorr) to 80 mTorr, such as 20 mTorr The DPN may be performed for a duration in a range from 20 seconds to 300 seconds.

The post-nitridation anneal process at block 114 may be a spike anneal and/or a laser anneal (e.g., a flash lamp anneal or a pulsed laser anneal). Generally, a spike anneal may be performed at a peak temperature equal to or greater than 1,100° C., such as equal to or greater than 1,150° C., in a processing chamber in which a gas mixture including nitrogen (N₂) gas and oxygen (O₂) gas is flowed. The flow rate of nitrogen (N₂) gas is much greater than a flow rate of oxygen (O₂) gas, such as in a ratio equal to or greater than 90:1 (N₂:O₂), and more particularly, in a ratio equal to or greater than 100:1 (N₂:O₂). Generally, a laser anneal (e.g., a flash lamp anneal) may reach a peak temperature equal to or greater than 1,250° C., such as in a range from 1,250° C. to 1,350° C., for a duration equal to or less than 800 milliseconds, such as in a range from 200 milliseconds to 400 milliseconds. In some examples, a laser anneal (e.g., a pulsed laser anneal) may reach a peak temperature equal to or greater than 1,250° C., such as in a range from 1,250° C. to 1,350° C., for a duration of equal to or less than 200 nanoseconds, such as in a range from 100 nanoseconds to 200 nanoseconds. The laser anneal may be performed in an ambient environment (e.g., the environment of the fab) or may be performed in, e.g., a nitrogen (N₂) environment. In some examples, either the spike anneal or the laser anneal may be performed at block 114. In some examples, both the spike anneal and the laser anneal, in any order, may be performed at block 114. The post-nitridation anneal process at block 114 may restore bonds that were broken during a preceding DPN (e.g., for substitution of oxygen by nitrogen) and may drive oxygen to, e.g., an oxide-silicon interface.

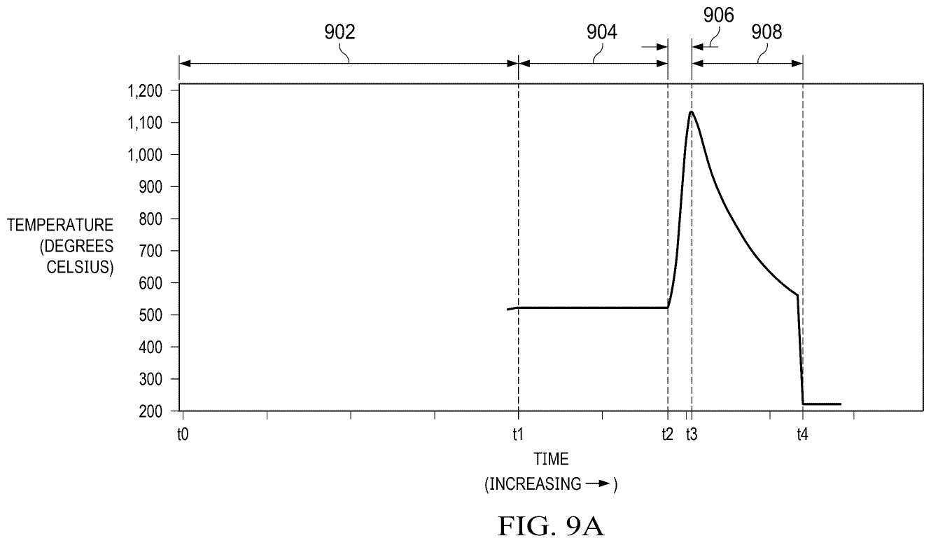

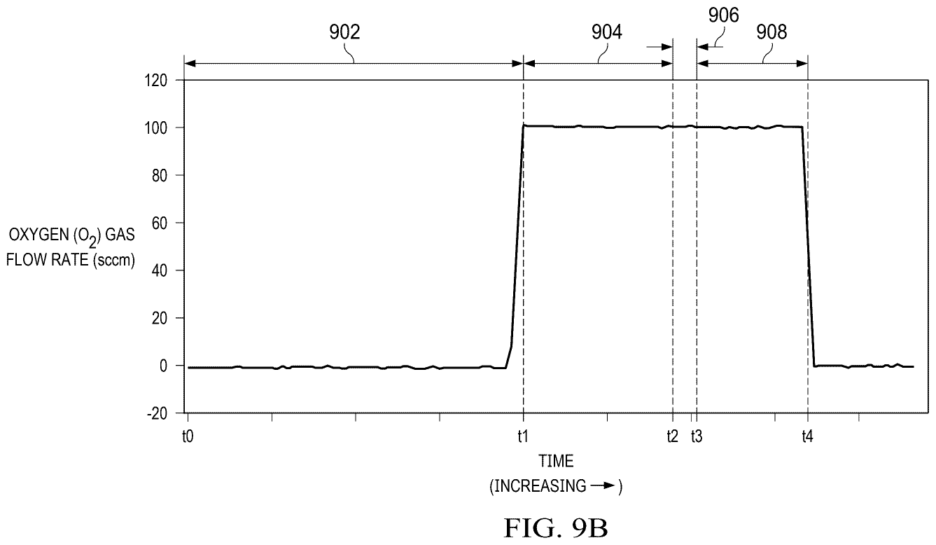

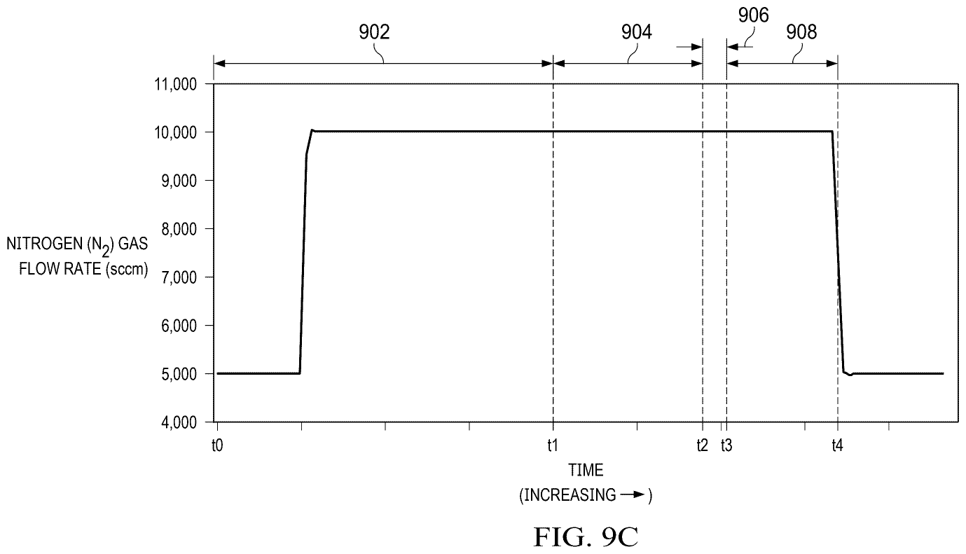

FIGS. 9A, 9B, and 9C are charts illustrating process parameters for an example spike anneal according to some examples. FIG. 9A shows temperature in degrees Celsius. FIG. 9B shows a flow rate of oxygen (O₂) gas in sccm. FIG. 9C shows a flow rate of nitrogen (N₂) gas in sccm. In some examples, the spike anneal is performed in a radiance chamber. The spike anneal includes a set-up period 902, a stabilization period 904, a ramp-up period 906, and a cool-down period 908.

At time t0, the semiconductor substrate 202 enter the processing chamber, and the set-up period 902 begins and continues to time t1. The temperature during the set-up period 902 may vary, e.g., depending on requirements of the processing chamber. Nitrogen (N₂) gas is flowed into the processing chamber beginning at time to at a rate of 5,000 sccm. The nitrogen (N₂) gas flow rate is subsequently increased during the set-up period to 10,000 sccm and is maintained throughout the remaining set-up period 902, the stabilization period 904, the ramp-up period 906, and the cool-down period 908 (e.g., maintained to time t4), as shown in FIG. 9C. No oxygen (O₂) gas is flowed into the processing chamber during the set-up period 902, as shown in FIG. 9B.

At time t1, the stabilization period 904 begins and continues to time t2. Throughout the stabilization period 904, the temperature is at a constant temperature in a range from 500° C. to 600° C. (e.g., approximately 525° C. as illustrated in FIG. 9A). At time t1, oxygen (O₂) gas begins to be flowed into the processing chamber beginning at a rate of 100 sccm and is maintained throughout the stabilization period 904, the ramp-up period 906, and the cool-down period 908 (e.g., maintained to time t4), as shown in FIG. 9B. The stabilization period 904 stabilizes the environment (e.g., including the gas flow rates) in the processing chamber for performing the spike anneal.

At time t2, the ramp-up period 906 begins and continues to time t3, at which time the temperature reaches a peak temperature. The peak temperature may be equal to or greater than 1,100° C., such as equal to or greater than 1,150° C. (e.g., equal to 1,150° C. as shown in FIG. 9A). As depicted in FIG. 9A, the temperature increases from the temperature of the stabilization period 904 at time t2 to the peak temperature at time t3. The duration from time t2 to time t3 may be in a range from 3 seconds to 5 seconds. The rate of increase of the temperature may be substantially linear and may be equal to or greater than 100° C. per second, and more particularly, equal to or greater than 160° C. per second.

Once the peak temperature is reached at time t3, the cool-down period 908 begins in which the temperature is decreased, as shown in FIG. 9A. The temperature may be decreased at any rate. In the illustrated example, the decrease in temperature varies in a range from 12° C. per second to about 50° C. per second. At time t4, the flow of oxygen (O₂) gas ceases, and the nitrogen (N₂) gas flow rate is decreased to 5,000 sccm. The semiconductor substrate 202 may then be transferred out of the processing chamber.

The formation of a gate oxide layer 302 as described above with respect to block 106 (including block 106, optionally block 110, block 112, and block 114) forms an oxide layer that includes nitrogen. The gate oxide layer 302 may be thinner (e.g., 25 Angstroms or less) with a greater peak concentration of nitrogen with less nitrogen penetration into the semiconductor substrate 202. In some examples, a thickness of the gate oxide layer 302 is equal to or less than 25 Angstroms (e.g., equal to or less than 21 Angstroms). In some examples, a peak nitrogen concentration in the gate oxide layer 302 is equal to or greater than 20 atomic percentage (at. %), and more particularly, equal to or greater than 25 at. %. In some examples, a concentration of nitrogen at an interface between the gate oxide layer 302 and the semiconductor material (e.g., silicon) of the semiconductor substrate 202 is equal to or less than 2 at. %, and more particularly, equal to or less than 1.25 at. % (e.g., equal to or less than 1.25 at. %).

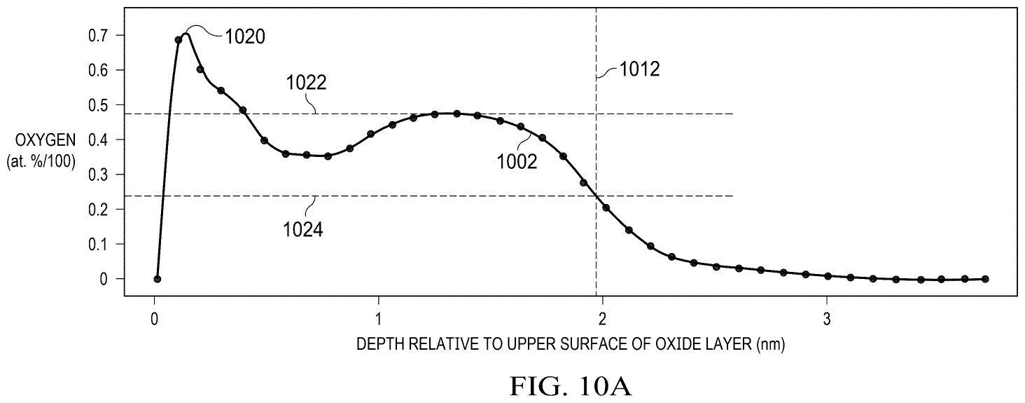

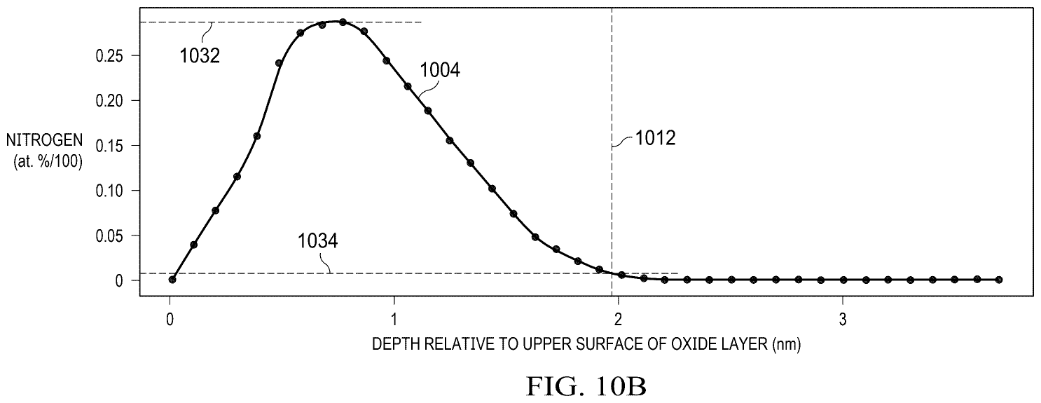

FIGS. 10A and 10B are charts of an oxygen concentration profile 1002 and a nitrogen concentration profile 1004, respectively, across a gate oxide layer 302 and into a semiconductor substrate 202 according to an example. The gate oxide layer 302 in this example is formed using an ISSG at 1,050° C. (at block 108), a DPN at 2 kW with 20% nitrogen (at block 112), and a spike anneal at 1,150° C. (at block 114), while omitting a pre-nitridation anneal (of block 110). The gate oxide layer 302 was formed on a silicon wafer, and hence, is silicon oxide including nitrogen. The profiles 1002, 1004 were determined using High Resolution Rutherford Backscattering (HR-RBS). FIGS. 10A and 10B show the respective profiles 1002, 1004 as an atomic percentage divided by 100 (along a y-axis) as a function of depth in nanometers (nm) relative to the upper surface of the gate oxide layer 302 (along an x-axis). Generally, given the chemical representation Si₍₁₋ᵣ₋ₛ₎OᵣNₛ, the y-axis in FIG. 10A shows the r value, and the y-axis in FIG. 10B is the s value.

As shown in FIG. 10A, the oxygen concentration profile 1002 has a surface peak oxygen concentration 1020 at or near the upper surface of the gate oxide layer 302 (e.g., at a depth of 0 nm). The oxygen concentration profile 1002 decreases to a trough and increases to a bulk peak oxygen concentration 1022. From the bulk peak oxygen concentration 1022, the oxygen concentration profile 1002 decreases to 0 at. % in the semiconductor substrate 202.

An oxide-silicon interface 1012 in FIGS. 10A and 10B is determined based on the oxygen concentration profile 1002. The bulk peak oxygen concentration 1022 is determined. As shown in FIG. 10A, the bulk peak oxygen concentration 1022 is approximately 47 at. %. A half-concentration 1024 is determined from the bulk peak oxygen concentration 1022. The half-concentration 1024 is half or 50% of the bulk peak oxygen concentration 1022. As shown in FIG. 10A, the half-concentration 1024 is approximately 23.5 at. %. The oxide-silicon interface 1012 is the depth at which the oxygen concentration profile 1002 (which results from forming the gate oxide layer 302) is at the half-concentration 1024. As shown in FIG. 10A, the oxide-silicon interface 1012 is at a depth of approximately 1.97 nm (e.g., approximately 19.7 Angstroms).

As shown in FIG. 10B, the nitrogen concentration profile 1004 increases from approximately 0 at. % at or near the upper surface of the gate oxide layer 302 (e.g., at a depth of 0 nm) and increases to a peak nitrogen concentration 1032. The peak nitrogen concentration 1032 in this example is approximately 28.5 at. %. The nitrogen concentration profile 1004 decreases from the peak nitrogen concentration 1032 to 0 at. % in the semiconductor substrate 202. The nitrogen concentration profile 1004 has an interface concentration 1034 where the nitrogen concentration profile 1004 is at the oxide-silicon interface 1012. The interface concentration 1034 is approximately 0.9 at. %.

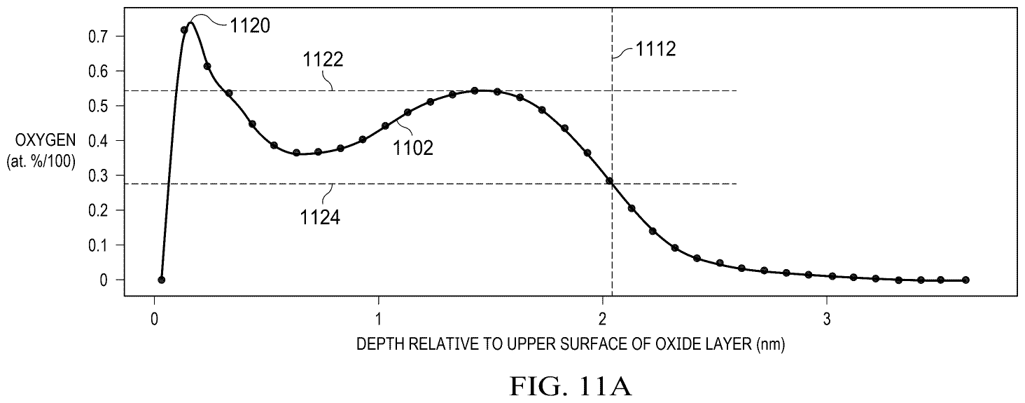

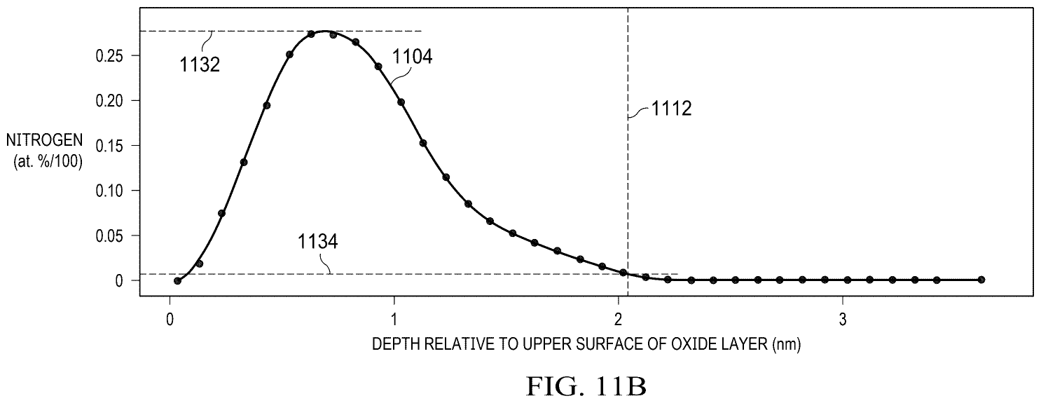

FIGS. 11A and 11B are charts of an oxygen concentration profile 1102 and a nitrogen concentration profile 1104, respectively, across a gate oxide layer 302 and into a semiconductor substrate 202 according to an example. The gate oxide layer 302 in this example is formed using an ISSG at 1,050° C. (at block 108), a DPN at 2 kW with 20% nitrogen (at block 112), and a spike anneal at 1,125° C. (at block 114), while omitting a pre-nitridation anneal (of block 110). The gate oxide layer 302 was formed on a silicon wafer, and hence, is silicon oxide including nitrogen. The profiles 1102, 1104 were determined using HR-RBS. FIGS. 11A and 11B show the respective profiles 1102, 1104 as an atomic percentage divided by 100 (along a y-axis) as a function of depth in nanometers (nm) relative to the upper surface of the gate oxide layer 302 (along an x-axis). Generally, given the chemical representation Si₍₁₋ᵣ₋ₛ₎OᵣNₛ, the y-axis in FIG. 11A shows the r value, and the y-axis in FIG. 11B is the s value.

As shown in FIG. 11A, the oxygen concentration profile 1102 has a surface peak oxygen concentration 1120 at or near the upper surface of the gate oxide layer 302 (e.g., at a depth of 0 nm). The oxygen concentration profile 1102 decreases to a trough and increases to a bulk peak oxygen concentration 1122. From the bulk peak oxygen concentration 1122, the oxygen concentration profile 1102 decreases to 0 at. % in the semiconductor substrate 202.

An oxide-silicon interface 1112 in FIGS. 11A and 11B is determined based on the oxygen concentration profile 1102. The bulk peak oxygen concentration 1122 is determined. As shown in FIG. 11A, the bulk peak oxygen concentration 1122 is approximately 54 at. %. A half-concentration 1124 is determined from the bulk peak oxygen concentration 1122. The half-concentration 1124 is half or 50% of the bulk peak oxygen concentration 1122. As shown in FIG. 11A, the half-concentration 1124 is approximately 27 at. %. The oxide-silicon interface 1112 is the depth at which the oxygen concentration profile 1102 (which results from forming the gate oxide layer 302) is at the half-concentration 1124. As shown in FIG. 11A, the oxide-silicon interface 1112 is at a depth of approximately 2.03 nm (e.g., approximately 20.3 Angstroms).

As shown in FIG. 11B, the nitrogen concentration profile 1104 increases from approximately 0 at. % at or near the upper surface of the gate oxide layer 302 (e.g., at a depth of 0 nm) and increases to a peak nitrogen concentration 1132. The peak nitrogen concentration 1132 in this example is approximately 27.5 at. %. The nitrogen concentration profile 1104 decreases from the peak nitrogen concentration 1132 to 0 at. % in the semiconductor substrate 202. The nitrogen concentration profile 1104 has an interface concentration 1134 where the nitrogen concentration profile 1104 is at the oxide-silicon interface 1112. The interface concentration 1134 is approximately 0.9 at. %.

As shown by FIGS. 10B and 11B, the peak nitrogen concentration 1032, 1132 in a gate oxide layer 302 may be equal to or greater than 20 at. % (and further, equal to or greater than 25 at. %), while keeping nitrogen penetration into the semiconductor substrate 202 at or below 2 at. % (and further, equal to or less than 1 at. %), when the gate oxide layer 302 has a thickness equal to or less than 25 Angstroms (e.g., equal to or less than 21 Angstroms). By having a higher peak nitrogen concentration in a thinner gate oxide layer with reduced nitrogen penetration into the semiconductor substrate, the corresponding nFET or pFET may have increased electrical properties. By having such relatively large peak nitrogen concentration 1032, 1132 in a relatively thin gate oxide layer 302, a magnitude of a slope of the nitrogen concentration profile 1004, 1104 may be equal to or greater than 2.5 at. % per Angstrom in a direction from the peak nitrogen concentration 1032, 1132 to the oxide-silicon interface 1012, 1112. Additionally, the bulk peak oxygen concentration 1022, 1122 may be equal to or greater than 40 at. % (e.g., equal to or greater than 45 at. %). Further, the concentration of oxygen at a depth of the peak nitrogen concentration 1032, 1132 may be equal to or less than 40 at. % (e.g., 37 at. % in FIGS. 9A and 9B and 35 at. % in FIGS. 10A and 10B).

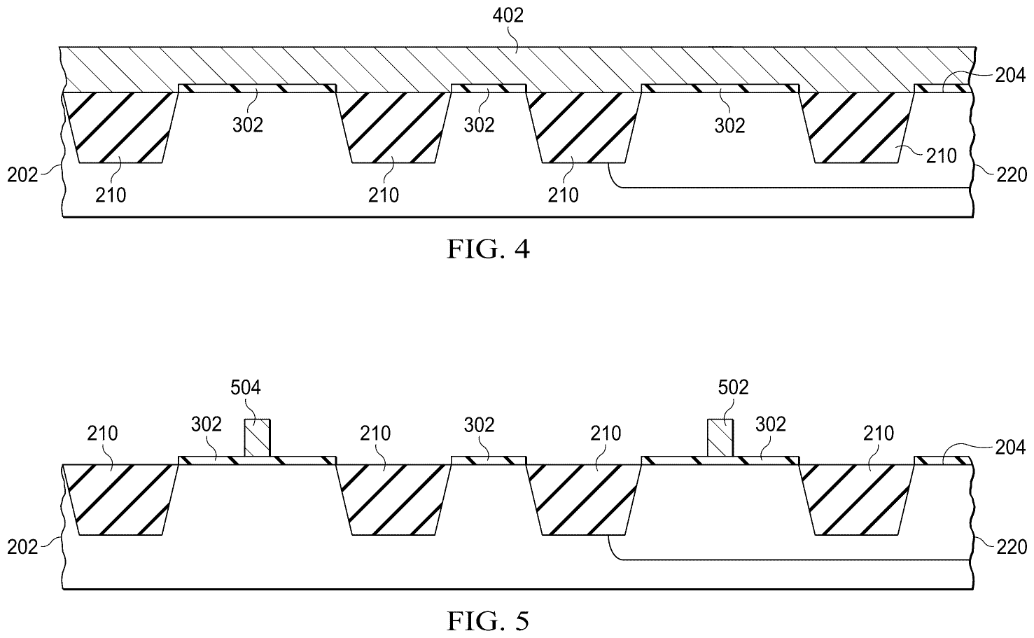

Referring to block 116 of FIG. 1 and to FIG. 4, a conductive gate layer 402 is formed over the gate oxide layer 302. The conductive gate layer 402 is formed over the gate oxide layer 302 and the isolation structures 210. In some examples, the conductive gate layer 402 is or includes a semiconductor material, such as polycrystalline silicon (polysilicon), and may be formed by any deposition process, such as CVD. In some examples, the semiconductor material may be doped in situ during deposition and/or may be implanted by a dopant after deposition. In some examples, the conductive gate layer 402 is polysilicon that is doped with a p-type dopant (e.g., boron (B)) with a concentration in a range from 1×10¹⁹ cm⁻³ to 1×10²¹ cm⁻³ in a region where a pFET is to be formed and is doped with an n-type dopant with a concentration in a range from 5×10¹⁹ cm⁻³ to 5×10²¹ cm⁻³ in a region where an nFET is to be formed.

Although not illustrated, a hardmask layer may be formed over the conductive gate layer 402, e.g., for subsequent patterning of the conductive gate layer 402. In some examples, the hardmask layer may be or include silicon nitride deposited by CVD, although other hardmask (e.g., dielectric) materials and/or other deposition processes may be used in other examples.

Referring to block 118 of FIG. 1 and to FIG. 5, the conductive gate layer 402 is patterned. The conductive gate layer 402 is patterned into gate electrodes 502, 504. In some examples, the hardmask layer is patterned corresponding to the pattern of the gate electrodes 502, 504, and using the patterned hardmask layer as a mask, the conductive gate layer 402 is patterned. The hardmask layer may be patterned using appropriate photolithography and etching processes, and the conductive gate layer 402 may be patterned using an appropriate etching process. For example, an anisotropic etch, such as an RIE, may be implemented.

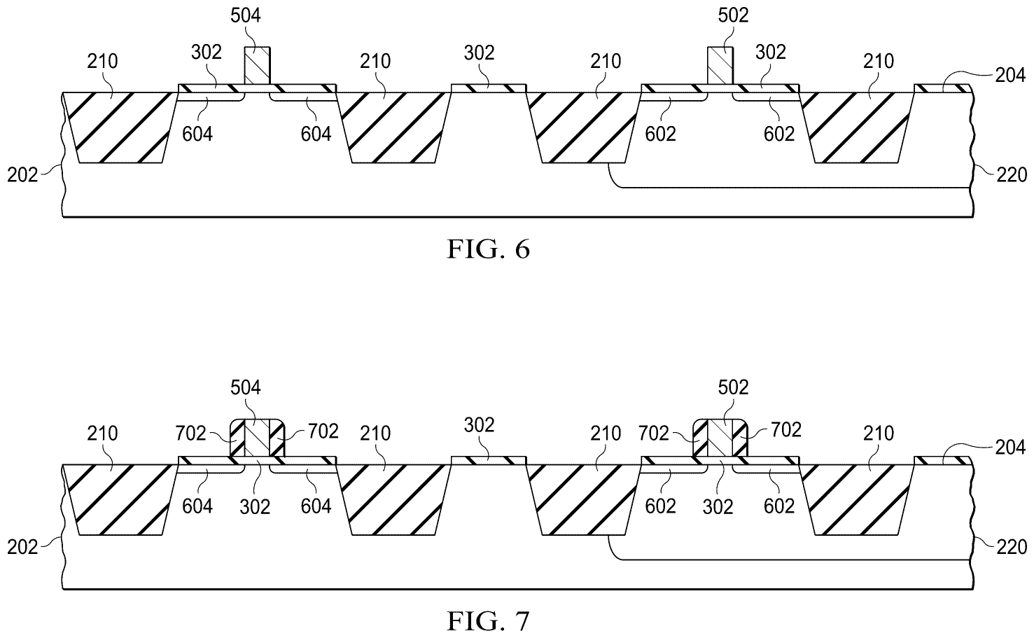

Referring to block 120 of FIG. 1 and to FIG. 6, lightly doped drain (LDD) regions are formed in the semiconductor substrate 202. As shown in FIG. 6, p-type LDD regions 602 and n-type LDD regions 604 are formed in the semiconductor substrate 202. The p-type LDD regions 602 are in the semiconductor substrate 202 on laterally opposing sides of the gate electrode 502, and the n-type LDD regions 604 are in the semiconductor substrate 202 on laterally opposing sides of the gate electrode 504. The p-type LDD regions 602 may be formed by masking (e.g., by a photoresist using photolithography) regions where p-type LDD regions are not to be formed and implanting a p-type dopant into the semiconductor substrate 202. The n-type LDD regions 604 may be formed by masking (e.g., by a photoresist using photolithography) regions where n-type LDD regions are not to be formed and implanting an n-type dopant into the semiconductor substrate 202. A concentration of the p-type dopant of the p-type LDD regions 602 is greater than a concentration of the p-type dopant of the p-type doped semiconductor substrate 202 and is greater than a concentration of the n-type dopant of the n-type doped well 220. A concentration of the n-type dopant of the n-type LDD regions 604 is greater than a concentration of the p-type dopant of the p-type doped semiconductor substrate 202. In some examples, the p-type LDD regions 602 are doped with a p-type dopant with a concentration in a range from 1×10¹⁹ cm⁻³ to 1×10²¹ cm⁻³, and the n-type LDD regions 604 are doped with an n-type dopant with a concentration in a range from 1×10¹⁹ cm⁻³ to 1×10²¹ cm⁻³.

Referring to block 122 of FIG. 1 and to FIG. 7, gate spacers 702 are formed on sidewalls of the gate electrodes 502, 504. The gate spacers 702 may be formed by depositing a layer of the material of the gate spacers 702 conformally over the semiconductor substrate 202 and anisotropically etching the layer such that the gate spacers 702 remain. The material of the gate spacers 702 may be any appropriate dielectric material, such as silicon nitride, silicon oxynitride, silicon carbon nitride, the like, or a combination thereof. The layer may be deposited by CVD, PECVD, atomic layer deposition (ALD), or the like. If a hardmask layer was used for patterning the conductive gate layer 402, any remaining portion of the hardmask layer may be removed from the gate electrodes 502, 504 when the layer forming the gate spacers 702 is etched.

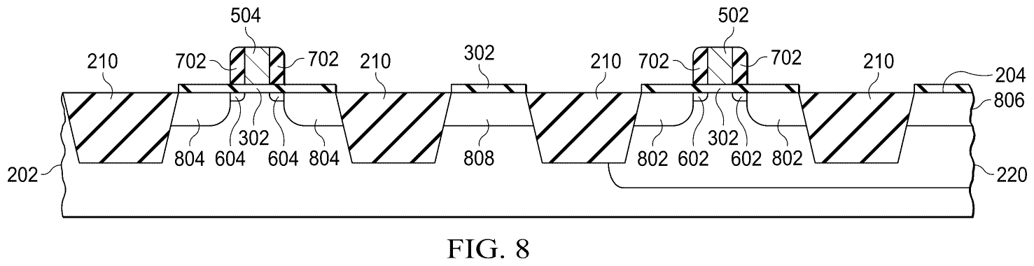

Referring to block 124 of FIG. 1 and to FIG. 8, source/drain regions are formed in the semiconductor substrate 202. P-type source/drain (PSD) regions 802 and n-type source/drain (NSD) regions 804 are formed in the semiconductor substrate 202, as shown in FIG. 8. The PSD regions 802 are on opposing lateral sides of the gate electrode 502 with the p-type LDD regions 602 therebetween. The NSD regions 804 are on opposing lateral sides of the gate electrode 504 with the n-type LDD regions 604 therebetween. Additionally, as shown in FIG. 8, an n-type substrate contact region 806 and a p-type substrate contact region 808 may be formed in the semiconductor substrate 202. An implantation is performed to form the PSD regions 802 and p-type substrate contact region 808. The PSD regions 802 and p-type substrate contact region 808 may be formed by masking (e.g., by a photoresist using photolithography) areas where p-type regions are not to be formed by the implantation and implanting a p-type dopant into the semiconductor substrate 202. An implantation is performed to form the NSD regions 804 and n-type substrate contact region 806. The NSD regions 804 and n-type substrate contact region 806 may be formed by masking (e.g., by a photoresist using photolithography) areas where n-type regions are not to be formed by the implantation and implanting an n-type dopant into the semiconductor substrate 202. A concentration of the p-type dopant of the PSD regions 802 and p-type substrate contact region 808 is greater than a concentration of the n-type dopant of the n-type doped well 220 and respective concentrations of the p-type dopant of the p-type LDD regions 602 and the p-type doped semiconductor substrate 202. A concentration of the n-type dopant of the NSD regions 804 and n-type substrate contact region 806 is greater than a concentration of the n-type dopant of the n-type LDD regions 604 and a concentration of the p-type dopant of the p-type doped semiconductor substrate 202, or if implemented, a p-type doped well in which the NSD regions 804 and n-type substrate contact region 806 are disposed. In some examples, the PSD regions 802 and p-type substrate contact region 808 are doped with a p-type dopant with a concentration in a range from 1×10¹⁹ cm⁻³ to 1×10²¹ cm⁻³. In some examples, the NSD regions 804 and n-type substrate contact region 806 are doped with an n-type dopant with a concentration in a range from 1×10¹⁹ cm⁻³ to 1×10²¹ cm⁻³.

In FIG. 8, a pFET and an nFET are shown formed on the semiconductor substrate 202. Subsequent processing may be performed on the semiconductor substrate 202 that includes the pFET and the nFET. For example, silicidation may be performed on the PSD regions 802, NSD regions 804, n-type substrate contact region 806, p-type substrate contact region 808, and gate electrodes 502, 504 to form respective silicides thereon. A dielectric layer (which may include multiple sub-layers) may be formed over the semiconductor substrate 202 and the gate electrodes 502, 504 (e.g., which may be over the silicides, if implemented). Respective metal contacts may then be formed through the dielectric layer to the PSD regions 802, NSD regions 804, n-type substrate contact region 806, p-type substrate contact region 808, and gate electrodes 502, 504, or to the silicides thereon. Subsequent back-end-of-the-line (BEOL) processing may thereafter be performed.

As illustrated by FIG. 8, a pFET includes the gate electrode 502, the gate oxide layer 302 underlying the gate electrode 502, the PSD regions 802 in the semiconductor substrate 202, the p-type LDD regions 602 in the semiconductor substrate 202, and a channel region in the semiconductor substrate 202. The channel region underlies (e.g., directly underlies) the gate electrode 502 and the gate oxide layer 302. The channel region is between the p-type LDD regions 602 and is between the PSD regions 802. One p-type LDD region 602 is between the channel region and a corresponding PSD region 802, and the other p-type LDD region 602 is between the channel region and the other PSD region 802. The gate oxide layer 302 underlying the gate electrode 502 has a thickness and nitrogen concentration as described above.

Similarly, as illustrated by FIG. 8, an nFET includes the gate electrode 504, the gate oxide layer 302 underlying the gate electrode 504, the NSD regions 804 in the semiconductor substrate 202, the n-type LDD regions 604 in the semiconductor substrate 202, and a channel region in the semiconductor substrate 202. The channel region underlies (e.g., directly underlies) the gate electrode 504 and the gate oxide layer 302. The channel region is between the n-type LDD regions 604 and is between the NSD regions 804. One n-type LDD region 604 is between the channel region and a corresponding NSD region 804, and the other n-type LDD region 604 is between the channel region and the other NSD region 804. The gate oxide layer 302 underlying the gate electrode 504 has a thickness and nitrogen concentration as described above.

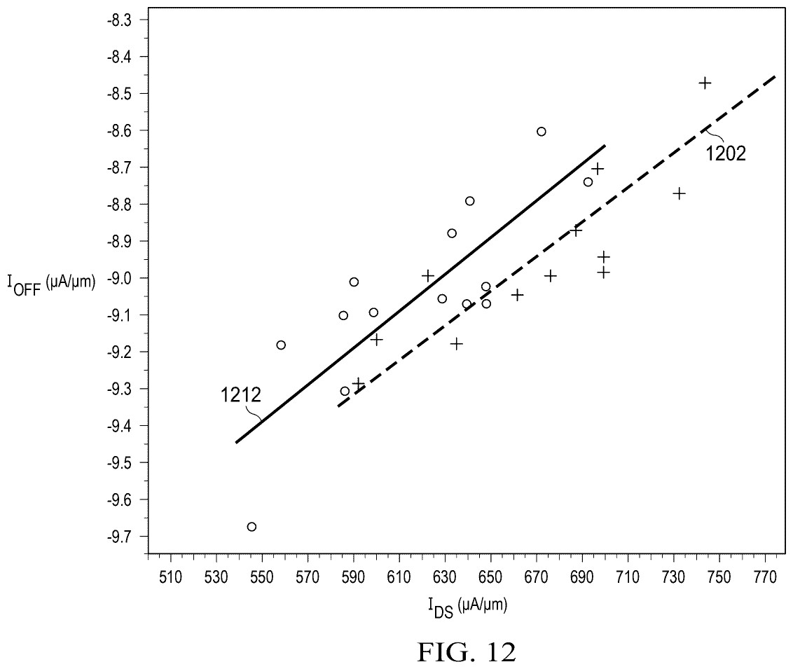

FIG. 12 is a chart depicting drain-to-source on current (Ips) versus off current (IOFF) for nFETs manufactured according to an example and nFETs manufactured according to a previous method. More specifically, gate oxide layers of the nFETs manufactured according to an example were manufactured using an ISSG at 1,050° C. (at block 108) and a spike anneal at 1,150° C. (at block 114). The gate oxide layers of all nFETs represented in FIG. 12 were approximately 20 Angstroms to 21 Angstroms thick. Individual samples of the nFETs manufactured according to an example are illustrated by +signs, while individual samples of and nFETs manufactured according to a previous method are illustrated by circles. FIG. 12 shows a mean line 1202 for the nFETs manufactured according to an example and a mean line 1212 for the nFETs manufactured according to a previous method. The nFETs manufactured according to an example showed a 5% to 7% improvement in IDs-IOFF.

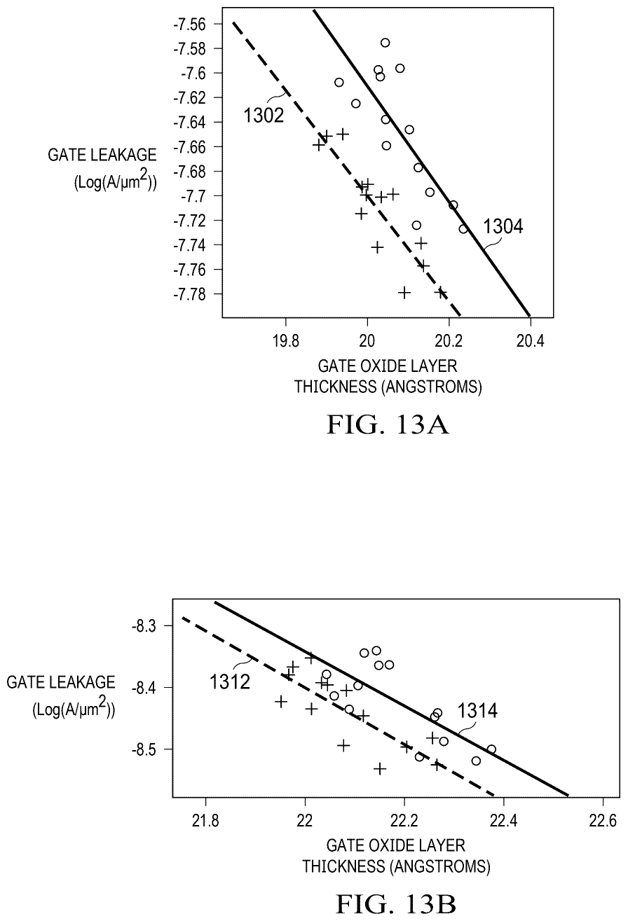

FIG. 13A is a chart depicting gate oxide layer thickness versus gate leakage for nFETs manufactured according to an example and nFETs manufactured according to a previous method. FIG. 13B is a chart depicting gate oxide layer thickness versus gate leakage for pFETs manufactured according to an example and pFETs manufactured according to a previous method. More specifically, gate oxide layers of the nFETs and pFETs manufactured according to an example were manufactured using an ISSG at 1,050° C. (at block 108) and a spike anneal at 1,150° C. (at block 114). Individual samples of the nFETs and pFETs manufactured according to an example are illustrated by +signs, while individual samples of nFETs and pFETs manufactured according to a previous method are illustrated by circles. The leakage current (e.g., y-axes) is shown in a logarithmic scale in decades. FIG. 13A shows a mean line 1302 for nFETs manufactured according to an example and a mean line 1304 for nFETs manufactured according to a previous method. FIG. 13B shows a mean line 1312 for pFETs manufactured according to an example and a mean line 1314 for pFETs manufactured according to a previous method. For nFETs, an improvement in gate leakage of approximately 0.1 decade was observed over the previous method, and for pFETs, an improvement in gate leakage of approximately 0.05 decade was observed over the previous method.

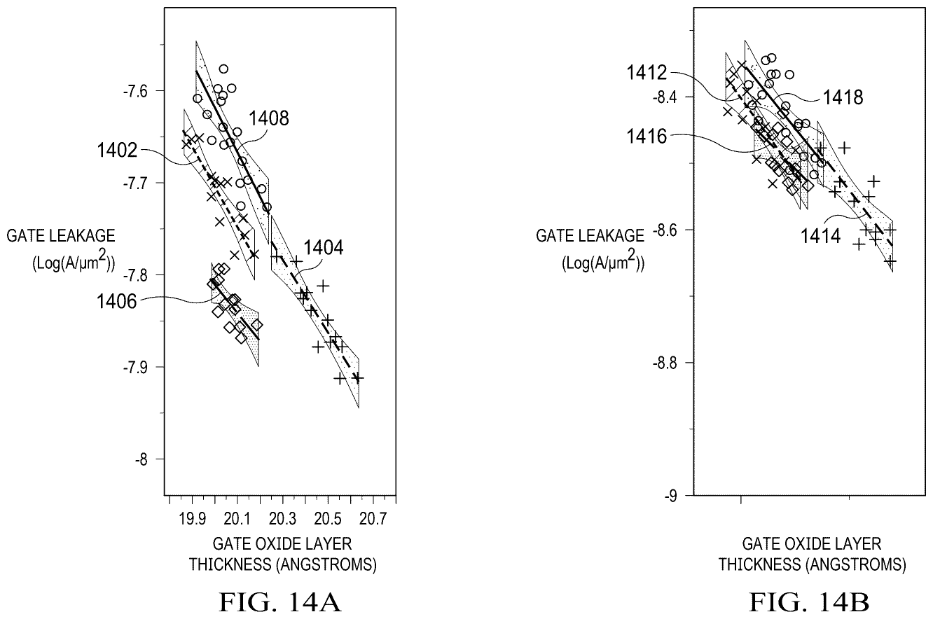

FIG. 14A is a chart depicting gate oxide layer thickness versus gate leakage for nFETs manufactured according to multiple examples and nFETs manufactured according to a previous method. FIG. 14B is a chart depicting gate oxide layer thickness versus gate leakage for pFETs manufactured according to multiple examples and pFETs manufactured according to a previous method. Individual samples of the nFETs and pFETs manufactured according to an example illustrated by x signs were manufactured using an ISSG at 1,050° C. (at block 108) and a spike anneal at 1,150° C. (at block 114). Individual samples of the nFETs and pFETs manufactured according to an example illustrated by +signs were manufactured using an ISSG at 1,050° C. (at block 108), a high nitrogen dose in the DPN (at block 112), and a laser anneal reaching 1,250° C. (at block 114). Individual samples of the nFETs and pFETs manufactured according to an example illustrated by signs were manufactured using an ISSG at 1,050° C. (at block 108), a low nitrogen dose in the DPN (at block 112), and a laser anneal reaching 1,250° C. (at block 114). Individual samples of the nFETs and pFETs manufactured according to a previous method are illustrated by circles. As shown in FIG. 14A, the nFET samples indicated by x signs have a mean line 1402; the nFET samples indicated by +signs have a mean line 1404; the nFET samples indicated by signs have a mean line 1406; and the nFET samples indicated by circles have a mean line 1408. As shown in FIG. 14B, the pFET samples indicated by x signs have a mean line 1412; the pFET samples indicated by +signs have a mean line 1414; the pFET samples indicated by signs have a mean line 1416; and the pFET samples indicated by circles have a mean line 1418. As shown by the results in FIGS. 14A and 14B, the examples have improved gate leakage relative to samples formed by a previous method.

Although various examples have been described in detail, it should be understood that various changes, substitutions, and alterations can be made therein without departing from the scope defined by the appended claims.

What is claimed is:

1. A semiconductor device, comprising:
a semiconductor substrate;
a gate oxide layer on the semiconductor substrate, the gate oxide layer having a thickness less than or equal to 25 Angstroms, the gate oxide layer comprising nitrogen and including a peak concentration of nitrogen that is equal to or greater than 20 atomic percent;
a gate electrode over the gate oxide layer;
a first source/drain region in the semiconductor substrate; and
a second source/drain region in the semiconductor substrate, the first source/drain region and the second source/drain region being on opposing lateral sides of the gate electrode.

2. The semiconductor device of claim 1, wherein the peak concentration of nitrogen is equal to or greater than 25 atomic percent.

3. The semiconductor device of claim 1, wherein a concentration of nitrogen in the gate oxide layer at an interface between the gate oxide layer and the semiconductor substrate is less than 2 atomic percent.

4. The semiconductor device of claim 1, wherein a concentration of nitrogen in the gate oxide layer at an interface between the gate oxide layer and the semiconductor substrate is less than 1.25 atomic percent.

5. The semiconductor device of claim 1, wherein a concentration of oxygen in the gate oxide layer at the peak concentration of nitrogen is equal to or less than 40 atomic percent.

6. The semiconductor device of claim 1, wherein a magnitude of a slope of a concentration of nitrogen between the peak concentration of nitrogen and an interface between the gate oxide layer and the semiconductor substrate is equal to or greater than 2.5 atomic percent per Angstrom.

7. A method, comprising:
forming a gate oxide layer on a semiconductor substrate, forming the gate oxide layer comprising oxidizing a surface of the semiconductor substrate;
performing a nitridation process on the gate oxide layer; and
performing a post-nitridation anneal on the gate oxide layer after performing the nitridation process, wherein the post-nitridation anneal includes at least one of:
performing a spike anneal at a temperature equal to or greater than 1,100° C.; and
performing a laser anneal at a temperature equal to or greater than 1,250° C.

8. The method of claim 7, further comprising performing a pre-nitridation anneal on the gate oxide layer before performing the nitridation process, the pre-nitridation anneal being performed at a temperature equal to or greater than 1,050° C.

9. The method of claim 8, wherein the pre-nitridation anneal is performed at a temperature equal to or greater than 1,050° C. for a duration equal to or less than 5 seconds.

10. The method of claim 8, wherein the pre-nitridation anneal includes flowing a gas mixture including oxygen (O₂) gas and nitrogen (N₂) gas.

11. The method of claim 7, wherein the post-nitridation anneal includes performing the spike anneal at a temperature equal to or greater than 1,100° C.

12. The method of claim 11, wherein the spike anneal is performed at a temperature equal to or greater than 1,150° C.

13. The method of claim 11, wherein performing the spike anneal at a temperature equal to or greater than 1,100° C. includes flowing a gas mixture including oxygen (O₂) gas and nitrogen (N₂) gas.

14. The method of claim 13, wherein a ratio of a flow rate of nitrogen (N₂) gas to a flow rate of oxygen (O₂) gas in the gas mixture is at least 100:1.

15. The method of claim 7, wherein the post-nitridation anneal includes performing the laser anneal at a temperature equal to or greater than 1,250° C.

16. The method of claim 15, wherein the laser anneal is performed at a temperature equal to or greater than 1,250° C. for a duration equal to or less than 800 milliseconds.

17. The method of claim 15, wherein the laser anneal includes a pulsed laser anneal performed for a duration equal to or less than 200 nanoseconds.

18. The method of claim 7, wherein oxidizing the surface of the semiconductor substrate includes flowing a gas mixture including hydrogen (H₂) gas and nitrous oxide (N₂O) gas.

19. The method of claim 18, wherein flowing the gas mixture is at a temperature in a range from 950° C. to 1,050° C.

20. The method of claim 7, further comprising:
after performing the post-nitridation anneal, depositing a gate layer on the gate oxide layer; and
patterning the gate layer into a gate electrode on the gate oxide layer.

21. A semiconductor device, comprising:
a semiconductor substrate; and
a nitrided oxide layer on the semiconductor substrate, the nitrided oxide layer having a thickness less than or equal to 25 Angstroms, the nitrided oxide layer including a peak concentration of nitrogen that is equal to or greater than 20 atomic percent, a concentration of nitrogen in the nitrided oxide layer at an interface between the nitrided oxide layer and the semiconductor substrate being less than 2 atomic percent.

22. The semiconductor device of claim 21, further comprising:
a gate electrode over the nitrided oxide layer; and
a source/drain region in the semiconductor substrate proximate the gate electrode.
